(19) United States
(12) Patent Application Publication
(10) Pub. No.: US 2021/0209264 A1
(43) Pub. Date: Jul. 8, 2021

(54) Modeling and calculation aerodynamic performances of multi-stage transonic axial compressors

(71) Applicant: VIETTEL GROUP, Ha Noi City (VN)

(72) Inventors: XUAN LONG BUI, Ha Noi City (VN); QUANG HAI NGUYEN, Ha Noi City (VN); TRUONG GIANG NGUYEN, Ha Noi City (VN); VAN SON PHAM, Ha Noi City (VN)

(73) Assignee: VIETTEL GROUP, Ha Noi City (VN)

(21) Appl. No.: 16/920,545

(22) Filed: Jul. 3, 2020

(30) Foreign Application Priority Data
Jan. 2, 2020 (VN) 1-2020-00036

(51) Int. Cl. G06F 30/15; G06T 17/20; B64D 33/02; B64C 21/02

(52) U.S. Cl. CPC G06F 30/15; B64C 21/02; B64D 33/02; G06T 17/20

(57) ABSTRACT

This invention refers to the method of modeling and calculating aerodynamic characteristics of a multi-stage axial compressor using commercial software, method to identify the stable working range of module. The method includes step 1: object modeling; step 2: constructing the calculation model; step 3: problem solving. Step 4: results analysis.

### BACKGROUND OF THE INVENTION

The invention refers to the method of modeling and calculating aerodynamic characteristics of a multi-stage axial compressor, equipped for jet engines. Since this type of engine is capable of providing many different power levels as well as a high thrust-to-weight and size ratio, they are widely used in the fields of aviation, maritime, energy industry and so on. Currently, with the development of science and technology, computer science in general, aviation, maritime together with energy industry are making great progress, widely applied in various military and civilian fields. Typically in the field of aviation, the flying equipment is constantly optimized to increase performance, reduce emission pollution, noise pollution, etc . . . . One of the key components is the engine—the equipment providing thrust and electric, pneumatic and hydraulic power to auxiliary systems. In the history of aviation development, many types of engines have been used such as internal combustion engine, turbo propeller engine, turbojet engine, turbofan engine. Currently turbofan engine with axial compressor has been developed along with widely used thanks to its ability to provide large thrust, fuel economy and low noise.

To optimize the performance of the turbofan engine, increase fuel economy, one of the current trends is to increase the compression ratio of the engine thereby increasing fuel burning efficiency. However, increasing the compression ratio of axial compressor often causes an increase in structural load, decrease in performance as well as narrower working range, so the design needs to be balanced with many factors. Meanwhile, designing axial compressor is inherently complex (large number of stage and input variables, high-performance requirement, stable working in many different conditions . . . ), therefore compressor optimization is even more complicated.

By the 1960s, 1970s, the designing method of axial compressor was mainly prototype and experimental design, requiring a lot of time with high cost but not efficiency, especially in the design improving and optimizing process. It was not until 1980s, 1990s, along with the development of computer science and computational techniques, the design of axial compressor using computation and numerical simulations began developing. However, due to the complexity of modeling and calculating vane machine in general and axial compressor in particular, the calculation was only applied to the individual compression stage in the first period. Recently, some commercial software has provided the ability to calculate multistage simultaneously and widely used such as ANSYS CFX, NUMECA FINE/Turbo, or some private solutions from NASA, Rolls—Royce automobile manufacturer. Nevertheless, the calculation result of multi-stage axial compressor depends heavily on modeling (physical model, flow model, calculation model, etc.) as well as calculation, that why designers need to develop their own calculation model.

Key Technical Features

With the above technical status, the purpose of the invention is to provide a method of modeling and calculating the aerodynamic characteristics of multi-stage axial compressor using commercial software ANSYS CFX. The calculation method is built on the engineers' knowledge basis about calculation object as well as the solver, serving the evaluation of axial compressor aerodynamic characteristics with proven accuracy through several standard models. The proposed method includes the following steps: Step 1: Modeling object; Step 2: Modeling the calculation model; Step 3: Calculating the aerodynamic performance of axial compressor by using ANSYS CFX solver; Step 4: Results analysis.

### BRIEF DESCRIPTION OF THE DRAWINGS

FIG. 1: Showing the process of modeling and calculating multi-stage axial compressor characteristics.

FIG. 2: Showing compressor performance diagram at a rotation speed.

FIG. 3: Showing the calculation model.

FIG. 4: Showing the rotor blades model.

FIG. 5: Showing the computational grid.

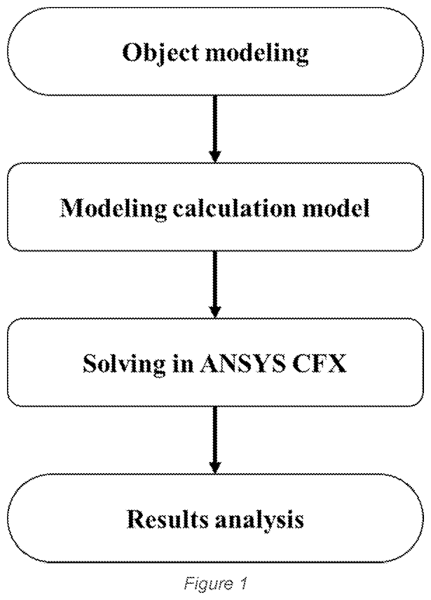

### DETAILED DESCRIPTION OF THE PREFERRED EMBODIMENT

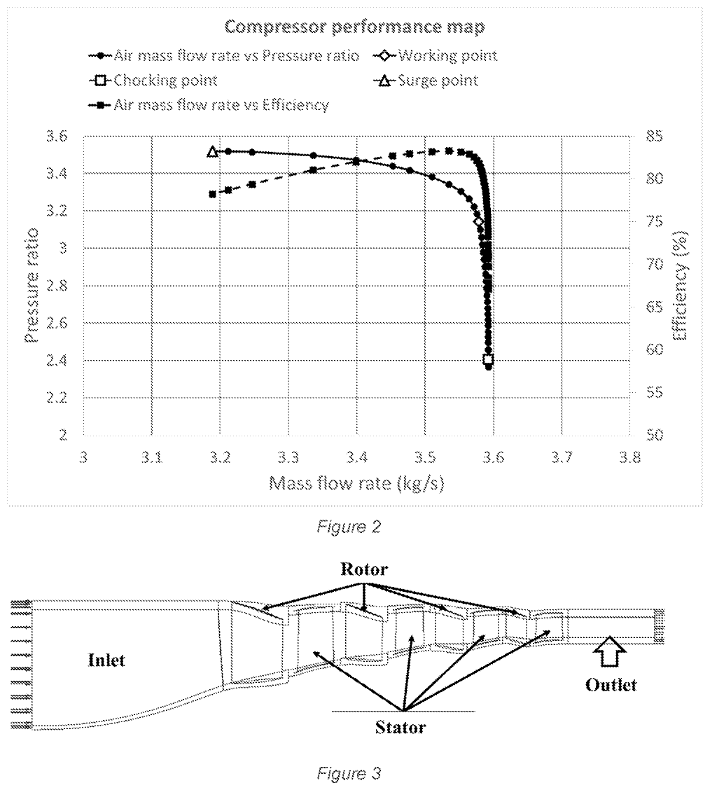

First, identify keys parameters of an universal compressor model: inlet mass flow rate, pressure ratio, total to total isentropic efficiency, surge margin and flow distribution at design point and off-design. FIG. 2 shows an example of standard compressor performance map, this chart is a part of calculation results.

Method of modeling and calculating aerodynamic characteristics of multi-stage axial compressors includes the following steps: Step 1: Modeling object; Step 2: Modeling the calculation model; Step 3: Solving in ANSYS CFX; Step 4: Results analysis. More precisely, this calculation procedure includes following steps:

Step 1: Modeling Object

From the characteristics of jet engines and multi-stage axial compressor components, object modeling is built on the assumption: ignoring the gravity effect (since the influence of gravity is full time and is very small compared to other force components such as axial force, centrifugal force) and friction at the bearings, compressor's design rotation speed is achieved, steady state working; the compressor is perfectly axisymmetric—the machining process is accurate, the compressor model is rigid—the structural characteristics are guaranteed; the blades are not vibrated, deformed during the operation.

Modeling objects includes the geometry of blades, flow path, design rotation speed, working fluid was model as ideal gas with thermodynamic properties is a function of temperature through a quadratic polynomial, and the flow is turbulent and viscous.

Step 2: Modeling the Calculation Model

The calculation model has a great influence on the accuracy of the calculation results. Herein calculation model was built base on engineer's knowledge and solver recommendations, then it has been validated by using test data of an existent compressor model (which is similarity in type, size, and working conditions of the studied object).

By using ANSYS CFX, pitch change modeling technique which uses the periodic boundary conditions was enabled to reduce the size of calculation model. CFX also provides various types of rotor-stator interfaces model as: frozen rotor, stage mixing and several transient blade row interfaces model. As a steady simulation, stage mixing interface model was selected. FIG. 3 is the meridional view of calculation model with 4 axial stages, each stage includes one rotor blade row and one stator blade row, each row was model as one blade; the inlet domain was model with real geometry of engine intake, outlet domain was model as straight duct; the length of inlet and outlet domain were set as 2 to 3 time of axial chord of the neighboring blade row.

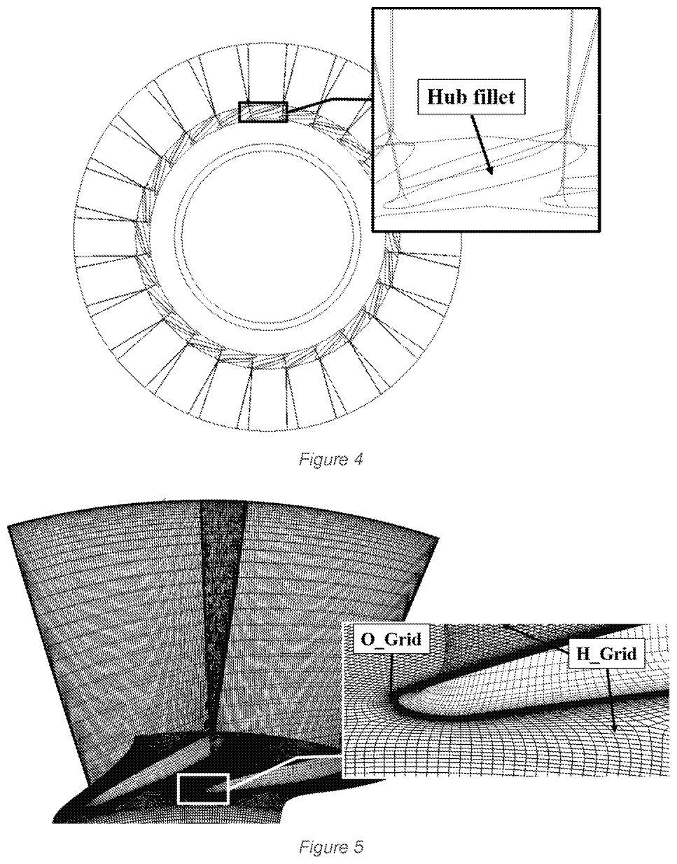

FIG. 4 presents 1^{st} rotor stage, blade fillet was included to taking into account its effects. Operating tip clearance of rotor blade was set to 0.6 time of cold tip gap. Blade surface roughness was setup depending on the manufacture method (3 micrometers for machining blade or larger for casting blade).

After blade flow path was defined, turbulence model was chosen, calculation grid was generated. FIG. 5 showing an example of calculation grid, O-H grid type was generated, in which the area surrounding blade uses O grid to follow the blade boundary while the remaining areas use H grid. The grid independence has been studied for each calculation to compromise the calculation grid size and the accuracy of the results.

Turbulence Intensity of flow: with the engine's air intake is relatively long, axial symmetry, the turbulence intensity is usually medium (5%) and can be corrected through validation models.

Turbulence model: to calculate interaction of the boundary layer near the wall, evaluate separation intensity at the blade suction surface, model k-ω SST is used with the reattachment option was enabled.

Step 3: Calculating the Axial Compressor Characteristics

Using CFX—Pre Preprocessing to setup problem, boundary conditions have been setup to investigate compressor performance at both design point and off-design. Ramping up RPM has been used, calculation starts from small rotation speeds (about 40% to 50% of the design rotation speed) then RPM will increase gradually.

For each rotation speed, the boundary condition at the compressor inlet uses the total pressure profile and the total temperature profile (these values normally set to ISA condition) with the profile data is taken from experiment or approximately by using blend factor. The boundary condition at the compressor outlet will be changed in correspondence with the possible working points of the compressor, specifically as follows:
When the calculated point is in the range from the choking point to the design point: outlet boundary condition will be set to the static average pressure, gradually increasing this static pressure value to move the calculated point on the constant rotation speed line.
When the calculated point is in the range from the design point to the surge point: outlet boundary condition will be set mass flow outlet, gradually decreasing this value to move the calculated point toward the surge point, near the surge point the calculated point was refined to find exact the surge point.
Corrected mass flow outlet can be used to automatically run the calculation across entire speed line.

The surge point is determined to be the point with the largest pressure ratio or the leftmost point at which the calculation is still stable and converges.

After the first calculated point converges (residual is less than 10⁻⁶ or the reference parameter value (pressure ratio, air mass flow, efficiency value) vary less than 0.001 after 300 nearest calculation step), the next calculated points will be initialized by the results from the previous convergence point.

A complete compressor performance map is constructed by calculating the compressor performance at different rotation speeds.

Step 4: Results Analysis

By benefit standard report template in CFX CFD—Post: Post processing, compressor aerodynamics performance and variety of flow characteristics can be extracted. This tool also supports to calculate other parameters by allows user to define parameter, expression and function beside the standard parameters. After apply this template, keys features of compressor will be calculated: air mass flow rate, compressor pressure ratio, total to total isentropic and polytrophic efficiency, temperature ratio, enthalpy rise, Mach number, pressure distribution . . . .

The compressor performance map is the summarizing of the results of calculation points. This diagram allows engineer to evaluate the performance characteristics and surge margin of the compressor. Specifically, surge margin was calculated as follows:

$$S M = ( \frac{{\dot{m}}_{p}}{{\dot{m}}_{s}} \times \frac{P {R}_{s}}{P {R}_{p}} - 1 ) \times 100 \%$$

In which:
\dot{m}ₚ: is the air mass flow rate at the highest efficiency point of compressor.
\dot{m}ₛ: is the air mass flow rate at the surge point.
PRₛ: is the pressure ratio at the surge point.
PRₚ: is the pressure ratio value at the highest efficiency point of compressor.

Usually with transonic compressors, this surge margin value is in the range of 12% to 20%.

Outside this domain, the compressor comes into unstable region.

1. Method of modeling and calculating performance of transonic multi-stage axial compressors includes:
Step 1: Modeling an object;
Step 2: Modeling a calculation model; using a stage mixing average interface model; Combined with the use of periodic boundary conditions, the calculation model is now modeled by a single blade element on each blade rows, an inlet domain was modeled using real geometry of an engine intake, an outlet domain was modeled as a straight duct with an inner diameter and a main outer diameter equal to an inner and an outer diameter of a final blade row; the length of these two domain is usually taken by 2 to 3 times an axial chord of a nearest blade row; a calculation mesh was generated by using a specialized meshing tool for turbomachinery, care must be taken about the mesh size and boundary layer to better capture all flow characteristics;
Step 3: Calculating the axial compressor performance by using commercial solver ANSYS CFX, a specialized solver for turbomachinery problem; boundary conditions have been setup to investigate compressor performance at both a design point and off-design; Ramping up RPM has been used, calculation starts from small rotation speeds (about 40% to 50% of a design rotation speed) then RPM will increase gradually; For each rotation speed, a total conditions profile (total pressure, total temperature at ISA or real condition) extracted from empirical testing or total condition with a blend factor correction model was used as inlet boundary conditions of calculation domain, outlet boundary condition can be set to average static pressure, air mass flow rate or corrected mass flow rate in correspondence with a position of calculate point in a speed line;
Step 4: Results analysis.

2. The method of modeling and calculating multi-stage transonic axial compressor performance according to claim 1, in which at the modeling of the calculation model step: geometry of the blades fillet was fully modeled in the calculation model; a rotor tip clearance height was set as 0.6 time of a cold tip clearance size; blade surface, hub surface and shroud surface roughness was taken by the ability of the machining method (approximately 3 micrometers), this value is bigger with casting blade; the roughness properties was setup at wall section of calculation model.

3. The method of modeling and calculating multi-stage transonic axial compressor performance according to claim 1, in which: at the modeling step, using a k-ω SST turbulent model, each blade has a mesh density of about one million elements, an area surrounding the blade is used O-grid to follow a blade boundary, the remaining areas use H-grid.

4. The method of modeling and calculating multi-stage transonic axial compressor performance according to claim 2, in which: at the modeling step, using a k-ω SST turbulent model, each blade has a mesh density of about one million elements, an area surrounding the blade is used O-grid to follow a blade boundary, the remaining areas use H-grid.

5. The method of modeling and calculating multi-stage transonic axial compressor performance according to claim 1, in which: at step 3—when the calculation points are in a range from a chocking point to a design working point: a boundary condition at the compressor outlet will be set to a static average pressure value, gradually increasing this static pressure value to move the calculated point on the speed line; When the calculated point is in a range from the design working point to the surge point: the boundary condition at the compressor outlet will be set to a value of air mass flow rate, gradually reducing this value to move the calculated point toward surge point in the speed line of constant rotation speed; the corrected mass flow rate can be used to automatically adjust the calculation across entire speed line.

6. The method of modeling and calculating multi-stage transonic axial compressor performance according to claim 2, in which: at step 3—when the calculation points are in a range from a chocking point to a design working point: a boundary condition at the compressor outlet will be set to a static average pressure value, gradually increasing this static pressure value to move the calculated point on the speed line; When the calculated point is in a range from the design working point to the surge point: the boundary condition at the compressor outlet will be set to a value of air mass flow rate, gradually reducing this value to move the calculated point toward surge point in the speed line of constant rotation speed; the corrected mass flow rate can be used to automatically adjust the calculation across entire speed line.

7. The method of modeling and calculating multi-stage transonic axial compressor performance according to claim 3, in which: at step 3—when the calculation points are in a range from a chocking point to a design working point: a boundary condition at the compressor outlet will be set to a static average pressure value, gradually increasing this static pressure value to move the calculated point on the speed line; When the calculated point is in a range from the design working point to the surge point: the boundary condition at the compressor outlet will be set to a value of air mass flow rate, gradually reducing this value to move the calculated point toward surge point in the speed line of constant rotation speed; the corrected mass flow rate can be used to automatically adjust the calculation across entire speed line.

8. The method of modeling and calculating multi-stage transonic axial compressor performance according to claim 4, in which: at step 3—when the calculation points are in a range from a chocking point to a design working point: a boundary condition at the compressor outlet will be set to a static average pressure value, gradually increasing this static pressure value to move the calculated point on the speed line; When the calculated point is in a range from the design working point to the surge point: the boundary condition at the compressor outlet will be set to a value of air mass flow rate, gradually reducing this value to move the calculated point toward surge point in the speed line of constant rotation speed; the corrected mass flow rate can be used to automatically adjust the calculation across entire speed line.

9. The method of modeling and calculating multi-stage transonic axial compressor performance according to claim 1, in which: after a first calculation point converges (calculation error is less than 10⁻⁶ or reference parameter value (pressure ratio, air mass flow, efficiency value) vary less than 0.001 after the last 300 calculation steps), a next calculation points will be initialized by a nearest convergence point; a complete compressor performance map is built by performing compressor performance calculations at different rotation speeds.

10. The method of modeling and calculating multi-stage transonic axial compressor performance according to claim 2, in which: after a first calculation point converges (calculation error is less than 10⁻⁶ or reference parameter value (pressure ratio, air mass flow, efficiency value) vary less than 0.001 after the last 300 calculation steps), a next calculation points will be initialized by a nearest convergence point; a complete compressor performance map is built by performing compressor performance calculations at different rotation speeds.

11. The method of modeling and calculating multi-stage transonic axial compressor performance according to claim 3, in which: after a first calculation point converges (calculation error is less than 10⁻⁶ or reference parameter value (pressure ratio, air mass flow, efficiency value) vary less than 0.001 after the last 300 calculation steps), a next calculation points will be initialized by a nearest convergence point; a complete compressor performance map is built by performing compressor performance calculations at different rotation speeds.

12. The method of modeling and calculating multi-stage transonic axial compressor performance according to claim 4, in which: after a first calculation point converges (calculation error is less than 10⁻⁶ or reference parameter value (pressure ratio, air mass flow, efficiency value) vary less than 0.001 after the last 300 calculation steps), a next calculation points will be initialized by a nearest convergence point; a complete compressor performance map is built by performing compressor performance calculations at different rotation speeds.

13. The method of modeling and calculating multi-stage transonic axial compressor performance according to claim 5, in which: after a first calculation point converges (calculation error is less than 10⁻⁶ or reference parameter value (pressure ratio, air mass flow, efficiency value) vary less than 0.001 after the last 300 calculation steps), a next calculation points will be initialized by a nearest convergence point; a complete compressor performance map is built by performing compressor performance calculations at different rotation speeds.

14. The method of modeling and calculating multi-stage transonic axial compressor performance according to claim 6, in which: after a first calculation point converges (calculation error is less than 10⁻⁶ or reference parameter value (pressure ratio, air mass flow, efficiency value) vary less than 0.001 after the last 300 calculation steps), a next calculation points will be initialized by a nearest convergence point; a complete compressor performance map is built by performing compressor performance calculations at different rotation speeds.

15. The method of modeling and calculating multi-stage transonic axial compressor performance according to claim 7, in which: after a first calculation point converges (calculation error is less than 10⁻⁶ or reference parameter value (pressure ratio, air mass flow, efficiency value) vary less than 0.001 after the last 300 calculation steps), a next calculation points will be initialized by a nearest convergence point; a complete compressor performance map is built by performing compressor performance calculations at different rotation speeds.

16. The method of modeling and calculating multi-stage transonic axial compressor performance according to claim 8, in which: after a first calculation point converges (calculation error is less than 10⁻⁶ or reference parameter value (pressure ratio, air mass flow, efficiency value) vary less than 0.001 after the last 300 calculation steps), a next calculation points will be initialized by a nearest convergence point; a complete compressor performance map is built by performing compressor performance calculations at different rotation speeds.
